(19) United States
(12) Patent Application Publication
(10) Pub. No.: US 2021/0184421 A1
(43) Pub. Date: Jun. 17, 2021

(54) Semiconductor Optical Element

(71) Applicant: Nippon Telegraph and Telephone Corporation, Tokyo (JP)

(72) Inventors: Takaaki Kakitsuka, Tokyo (JP); Shinji Matsuo, Tokyo (JP)

(21) Appl. No.: 17/049,520

(22) PCT Filed: Apr. 12, 2019
(86) PCT No.: PCT/JP2019/016007

§ 371 Date: Oct. 21, 2020

(30) Foreign Application Priority Data
Apr. 23, 2018 (JP) 2018-082022

(51) Int. Cl. H01S 5/026; H01S 5/042; H01S 5/343; H01S 5/12

(52) U.S. Cl. CPC H01S 5/026; H01S 5/12; H01S 5/3434; H01S 5/04256

(57) ABSTRACT

A first conduction type first cladding layer and a second conduction type second cladding layer are arranged on the two sides in the vertical direction of a core portion having a multiple quantum-well structure, and a first conduction type third cladding layer and a second conduction type fourth cladding layer are arranged on the two sides in the horizontal direction of the core portion. A first electrode connected to the third cladding layer is formed. A second electrode connected to the fourth cladding layer is formed. A reverse bias is applied between the first and third cladding layers and the second and fourth cladding layers.

### CROSS-REFERENCE TO RELATED APPLICATIONS

This application is a national phase entry of PCT Application No. PCT/JP2019/016007, filed on Apr. 12, 2019, which claims priority to Japanese Application No. 2018-082022, filed on Apr. 23, 2018, which applications are hereby incorporated herein by reference.

### TECHNICAL FIELD

The present invention relates to a semiconductor optical element having a multiple quantum-well structure.

### BACKGROUND ART

An explosive increase in a network traffic volume due to the spread of the Internet leads to a considerable increase in speed and capacity of optical fiber transmission. Development of semiconductor lasers as light source devices that play an important role in optical fiber communication has advanced. In particular, the realization of a single-mode light source using a distributed feedback (DFB) laser significantly contributes to an increase in speed and capacity of optical fiber communication using time division multiplexing and wavelength division multiplexing (WDM).

In recent years, optical communication is applied to not only the telecom field including a core network, a metro network, and the like but also short-distance data communication between data centers, between racks, and between boards. For example, 100-Gb Ethernet (registered trademark) is standardized using a configuration of a WDM-type multi-wavelength array light source, and the capacity of data communication has been increased sharply. In view of these circumstances, an increase in speed and a reduction in power consumption of optical transmitters are absolutely required, and modulator-integrated-type semiconductor lasers have been developed as high-performance modulation light sources that modulate light emitted from an integrated laser light source using electric signals and output the thus-obtained modulated light.

In particular, EA-DFB lasers obtained by monolithically integrating a single-mode DFB laser and an electro absorption (EA) optical modulator on one substrate are small in size, consume less power, and can perform high-speed modulation at a speed faster than 40 Gbit/s (Non Patent Literature 1). Therefore, the EA-DFB lasers have come into practical use as optical transmitters for a relatively short distance, which is 100 km or less. At present, the standardization of 400-Gbit Ethernet is being achieved, and there is demand for EA-DFB lasers that are compatible with PAM (Pulse Amplitude Modulation) of the 50 Gbit/s class.

EA modulators modulate light utilizing a change in the optical absorption coefficient when an electric field generated by a modulating electric signal is applied to a quantum-well active layer serving as an optical waveguide core through which light to be modulated passes. Here, a conceptual configuration of a common EA modulator will be described with reference to FIG. 6. This EA modulator has a pin semiconductor structure including a first cladding layer 301 that is made of an n-type compound semiconductor, a core portion 302 that is formed on the first cladding layer 301 and serves as an active region having a multiple quantum-well structure, and a second cladding layer 303 that is formed on the core portion 302 and is made of a p-type compound semiconductor. The first cladding layer 301 is provided with an electrode 304, and the second cladding layer 303 is provided with an electrode 305. It should be noted that FIG. 6 shows a cross section taken along a plane orthogonal to the light guiding direction.

A quantum-well layer included in the core portion 302 has a multi-layer structure in which a plurality of barrier layers made of a material with a large band gap and a plurality of well layers made of a material with a small band gap are stacked alternately and periodically. Together with a modulating electric signal from a modulating signal source, a reverse bias is applied by the electrode 304 and the electrode 305, and thus an electric field is applied in the vertical direction, namely the layer stacking direction. Accordingly, the optical absorption coefficient with respect to light passing through the core portion 302 is controlled, and thus the light is modulated.

Next, an EA-DFB laser element in which an EA modulator 300a as described above and a DFB laser 300b are combined will be described with reference to FIG. 7. FIG. 7 shows a cross section taken along a plane that is parallel to the light guiding direction and orthogonal to the layer stacking direction. A first cladding layer 301, a second cladding layer 303, and an electrode 304 are shared by the EA modulator 300a and the DFB laser 300b. In the DFB laser 300b, a diffraction grating 306 for forming a distributed Bragg reflector structure is formed on an active portion 302a having a quantum-well structure.

In the EA modulator 300a, an electrode 305 is formed on the second cladding layer 303 via a p contact layer 307, and in the DFB laser 300b, an electrode 305a is formed on the second cladding layer 303 via a p contact layer 307a. The EA modulator 300a and the DFB laser 300b are electrically separated by a region between the electrode 305 and the electrode 305a, and are independently subjected to bias driving.

In this EA-DFB laser element, the EA modulator 300a and the DFB laser 300b are formed extending along the core portion 302, and a laser beam generated in the DFB laser 300b is modulated by the EA modulator 300a and then output.

A change in the absorption coefficient (optical absorption spectrum) of the core portion 302 in the EA modulator 300a in the above-described EA-DFB laser element will be described with reference to FIG. 8. It should be noted that, in FIG. 8, the solid line indicates the result from a case where no electric field is applied to the EA modulator 300a, and the dotted line indicates the result from a case where an electric field is applied to the EA modulator 300a. The optical absorption spectrum of the core portion 302 includes interband absorption corresponding to an interband transition wavelength, and an exciton absorption peak located on the long wavelength side of the interband absorption.

When an electric field is applied, a so-called quantum-confined Stark effect (QCSE) is exhibited. Specifically, the exciton absorption peak of the optical absorption spectrum is lowered due to the localization of carriers in the quantum-well layer, and the absorption spectrum is shifted to the long wavelength side due to a reduction in the effective band gap. Optical modulation is achieved utilizing a change in the absorption coefficient at the laser oscillation wavelength caused by the electric field.

Even if an electric field is applied to the core portion in a direction parallel to the layers in the quantum-well layer, electro absorption can be caused. This lateral electric field application structure will be described with reference to FIG. 9. The lateral electric field application structure (lateral pin structure) includes a first cladding layer 401 made of an i-type compound semiconductor, a core portion 402 that is formed on the first cladding layer 401 and serves as an active region having a multiple quantum-well structure, a second cladding layer 403 that is formed on the core portion 402 and is made of an i-type compound semiconductor, a third cladding layer 404 that is formed on one side portion of the core portion 402 and is made of a first conduction type compound semiconductor, and a fourth cladding layer 405 that is formed on the other side portion of the core portion 402 and is made of a second conduction type compound semiconductor. The lateral electric field application structure further includes an electrode 406 connected to the third cladding layer 404, and an electrode 407 connected to the fourth cladding layer 405.

An electric field is applied in the horizontal direction by providing a modulating electric signal generated by a modulating signal source to the electrode 406 and the electrode 407. A change in the absorption coefficient (optical absorption spectrum) of the core portion 402 in an EA modulator having the above-described lateral electric field application structure will be described with reference to FIG. 10. It should be noted that, in FIG. 10, the solid line indicates the result from a case where no electric field is applied to the EA modulator, and the dotted line indicates the result from a case where an electric field is applied to the EA modulator.

At this time, the change in the absorption coefficient of the core portion 402 is caused mainly by an exciton absorption blocking effect of the electric field (see Non Patent Literature 2). The exciton absorption peak is lowered due to the application of an electric field and thus the absorption spectrum is broadened. In addition, the absorption at the band end is changed due to the two-dimensional Franz-Keldysh effect, and thus the absorption coefficient increases on the long wavelength side with respect to the exciton absorption peak.

Next, the results obtained by comparing the quenching properties of the above-described EA modulators relative to the electric field directions are shown in FIG. 11 and FIG. 12. FIG. 11 shows the results from the EA modulator in which an electric field is applied in the quantum well stacking direction (vertical direction), and FIG. 12 shows the results from the EA modulator having a lateral electric field application structure. It should be noted that the quantum well in the quantum-well structure included in the core portion 402 includes six quantum-well layers that are made of InGaAsP and have a thickness of 10 nm. In the quantum-well structure, the wavelength between ground levels is 1.48 μm, the core length is 0.7 μm, the length of the modulator region is 200 μm, and the wavelength is 1.55 μm. FIG. 11 and FIG. 12 show the results obtained by comparing the quenching properties of the modulators relative to the electric field directions. FIG. 11 shows the results from the case where an electric field is applied in the vertical direction, and FIG. 12 shows the results from the case where an electric field is applied in the horizontal direction.

In the case where an electric field is applied in the vertical direction, the absorption spectrum is shifted to the long wavelength side due to an increase in an effective band gap wavelength, and a high quenching ratio can be obtained, but in this case, it is required to increase the bias voltage value. On the other hand, with the lateral electric field application structure, a high quenching ratio can be obtained in a low voltage region due to a drastic exciton blocking effect, but the quenching ratio tends to saturate after the exciton has been quenched, and thus the wavelength region that can provide a sufficient quenching ratio is limited.

### CITATION LIST

### Non Patent Literature

NPL 1 W. Kobayashi et al., “Design and Fabrication of 10-/40-Gb/s, Uncooled Electroabsorption Modulator Integrated DFB Laser With Butt-Joint Structure”, Journal of Lightwave Technology, vol. 28, no. 1, pp. 164-171, 2010.
NPL 2—D. A. B. Miller et al., “Electric field dependence of optical absorption near the band gap of quantum-well structures”, Physical Review, vol. B32, pp. 1043-1060, 1985.
NPL 3 E. H. Sargent et al., “OEIC-Enabling LCI Lasers with Current Guides: Combined Theoretical-Experimental Investigation of Internal Operating Mechanisms”, IEEE Journal of Quantum Electronics, vol. 34, no. 7, pp. 1280-1287, 1998.

### SUMMARY

### Technical Problem

As described above, a conventional technique has a problem in that the configuration in which an electric field is applied in the vertical direction requires high voltage to obtain a high quenching ratio, and, with the configuration in which an electric field is applied in the lateral direction, a high quenching ratio is obtained at a low voltage while a wavelength region that can provide a sufficient quenching ratio is limited.

Embodiments of the present invention were achieved in order to solve the foregoing problems, and an object thereof is to make it possible to obtain a sufficient quenching ratio in a wide wavelength region at a low voltage when performing electro-absorption optical modulation.

### Means for Solving the Problem

A semiconductor optical element according to embodiments of the present invention includes: a first cladding layer that is made of a first conduction type compound semiconductor; a core portion that is formed on the first cladding layer and serves as an active region having a multiple quantum-well structure including a barrier layer made of a compound semiconductor and a quantum-well layer made of a compound semiconductor; a second cladding layer that is formed on the core portion and is made of a second conduction type compound semiconductor; a third cladding layer that is formed on one side portion of the core portion and is made of a first conduction type compound semiconductor; and a fourth cladding layer that is formed on the other side portion of the core portion and is made of a second conduction type compound semiconductor, wherein a reverse bias is applied between the first and third cladding layers and the second and fourth cladding layers, and electric field application means for applying electric fields to the core portion is constituted by the first cladding layer, the second cladding layer, the third cladding layer, and the fourth cladding layer.

The above-mentioned semiconductor optical element may further include: a first optical confinement separate layer that is formed between the first cladding layer and the core portion and is made of an i-type compound semiconductor; and a second optical confinement separate layer that is formed between the core portion and the second cladding layer and is made of an i-type compound semiconductor.

The above-mentioned semiconductor optical elements further include: a first electrode connected to the third cladding layer; and a second electrode connected to the fourth cladding layer.

A configuration may also be employed in which the above-mentioned semiconductor optical elements include: an optical modulation region including the first cladding layer, the second cladding layer, the core portion, the third cladding layer, and the fourth cladding layer; and a laser region including an active portion having a multiple quantum-well structure that shares the first cladding layer and the second cladding layer with the optical modulation region, and a diffraction grating formed on the active portion, wherein the optical modulation region and the laser region are arranged to be insulated and separated from each other, and the optical modulation region and the laser region are optically connected to each other.

### Effects of Embodiments of the Invention

As described above, with embodiments of the present invention, the configuration is employed in which the first conduction type first cladding layer and the second conduction type second cladding layer are arranged on the two sides in the vertical direction of the core portion having a multiple quantum-well structure, the first conduction type third cladding layer and the second conduction type fourth cladding layer are arranged on the two sides in the horizontal direction of the core portion, and a reverse bias is applied thereto, and thus an excellent effect is obtained that a sufficient quenching ratio is obtained in a wide wavelength region at a low voltage when performing electro-absorption optical modulation.

### BRIEF DESCRIPTION OF THE DRAWINGS

FIG. 1 is a cross-sectional view showing the configuration of a semiconductor optical element according to an embodiment of the present invention.

FIG. 2A shows cross-sectional views showing the configuration of another semiconductor optical element according to the embodiment of the present invention.

FIG. 2B is a perspective view showing the configuration of the other semiconductor optical element according to the embodiment of the present invention.

FIG. 3 is a characteristic diagram showing the results obtained by comparing the quenching properties in an EA modulation region of the semiconductor optical element according to the embodiment of the present invention relative to the electric field directions.

FIG. 4A shows cross-sectional views showing the configuration of another semiconductor optical element according to the embodiment of the present invention.

FIG. 4B is a perspective view showing the configuration of another semiconductor optical element according to the embodiment of the present invention.

FIG. 5 is a cross-sectional view showing the configuration of another semiconductor optical element according to the embodiment of the present invention.

FIG. 6 is a cross-sectional view showing the configuration of a conventional EA modulator.

FIG. 7 is a cross-sectional view showing the configuration of an EA-DFB laser element in which the conventional EA modulator and a DFB laser are combined.

FIG. 8 is a characteristic diagram showing a change in the absorption coefficient (optical absorption spectrum) of a core portion of the EA modulator.

FIG. 9 is a cross-sectional view showing the configuration of a conventional EA modulator.

FIG. 10 is a characteristic diagram showing a change in the absorption coefficient (optical absorption spectrum) of a core portion of the EA modulator.

FIG. 11 is a characteristic diagram showing the quenching properties of an EA modulator.

FIG. 12 is a characteristic diagram showing the quenching properties of an EA modulator.

### DETAILED DESCRIPTION OF ILLUSTRATIVE EMBODIMENTS

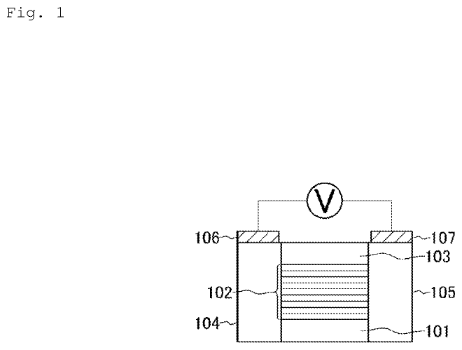

Hereinafter, a semiconductor optical element according to an embodiment of the present invention will be described with reference to FIG. 1. This semiconductor optical element includes a first cladding layer 101, a core portion 102 formed on the first cladding layer 101, and a second cladding layer 103 formed on the core portion 102. The core portion 102 is formed in contact with the top face of the first cladding layer 101, and the second cladding layer 103 is formed in contact with the top face of the core portion 102.

In addition, this semiconductor optical element includes a third cladding layer 104 formed on one side portion of the core portion 102, and a fourth cladding layer 105 formed on the other side portion of the core portion 102. The third cladding layer 1o4 is formed in contact with one side portion of the core portion 102, and the fourth cladding layer 105 is formed in contact with the other side portion of the core portion 102.

The first cladding layer 101 is made of a first conduction type compound semiconductor, and the second cladding layer 103 is made of a second conduction type compound semiconductor. The core portion 102 is formed to have a multiple quantum-well structure including barrier layers made of a compound semiconductor and quantum-well layers made of a compound semiconductor, and serves as an active region.

The third cladding layer 104 is made of a first conduction type compound semiconductor, and the fourth cladding layer 105 is made of a second conduction type compound semiconductor. It should be noted that FIG. 1 shows a cross section that is orthogonal to a light guiding direction in which light is guided in an optical waveguide formed by the core portion 102. The core portion 102 extends from the front side of the plane of FIG. 1 toward the back side thereof.

The semiconductor optical element according to the embodiment further includes a first electrode 106 connected to the third cladding layer 104, and a second electrode 107 connected to the fourth cladding layer 105. The semiconductor optical element is operated by using the first electrode 1o6 and the second electrode 107 to apply a reverse bias between the first conduction type (e.g., n-type) first and third cladding layers 101 and 104 and the second conduction type (e.g., p-type) second and fourth cladding layers 103 and 105. The semiconductor optical element according to the embodiment is an electro absorption optical modulation element.

As described above, in the semiconductor optical element according to the embodiment, a reverse bias is applied between the first and third cladding layers 101 and 103 and the second and fourth cladding layers 102 and 104. Electric field application means for applying electric fields to the core portion 102 is constituted by the first cladding layer 101, the second cladding layer 102, the third cladding layer 103, and the fourth cladding layer 104. In other words, the first cladding layer 101, the second cladding layer 102, the third cladding layer 103, and the fourth cladding layer 104 are electric field application layers for applying electric fields to the quantum-well layers in the core portion 102 in both a direction parallel to the stacking direction and a direction orthogonal to the stacking direction.

As described above, with the embodiment, electric fields are applied to the core portion 102 having a multiple quantum-well structure in the vertical direction and the lateral direction. When electric fields are applied in this manner, the absorption of an exciton is blocked by the lateral electric field if the applied electric fields are small, and thus a drastic change in optical absorption occurs. If large electric fields are applied, the band end is shifted to the long wavelength side due to the vertical electric field, and thus the optical absorption region is shifted to the long wavelength side, thus making it possible to keep a drastic change in absorption caused by the band end absorption. In addition, with the embodiment, carriers are swept in the horizontal (lateral) direction at a high speed, thus making it possible to realize high-speed modulation.

It should be noted that a configuration may also be employed in which the third cladding layer 104 is of the second conduction type, and the fourth cladding layer 105 is the first conduction type. In the description above, a case where the first cladding layer 101 and the third cladding layer 104 are the n-type and the second cladding layer 103 and the fourth cladding layer 105 are the p-type, and a case where the first cladding layer 101 and the third cladding layer 104 are the p-type and the second cladding layer 103 and the fourth cladding layer 105 are the n-type are described. There is no limitation to these cases, and a configuration may also be employed in which the first cladding layer 101 and the fourth cladding layer 105 are of the n-type, and the third cladding layer 104 and the second cladding layer 103 are of the p-type. Furthermore, a configuration may also be employed in which the first cladding layer 101 and the fourth cladding layer 105 are of the p-type, and the third cladding layer 104 and the second cladding layer 103 are of the n-type.

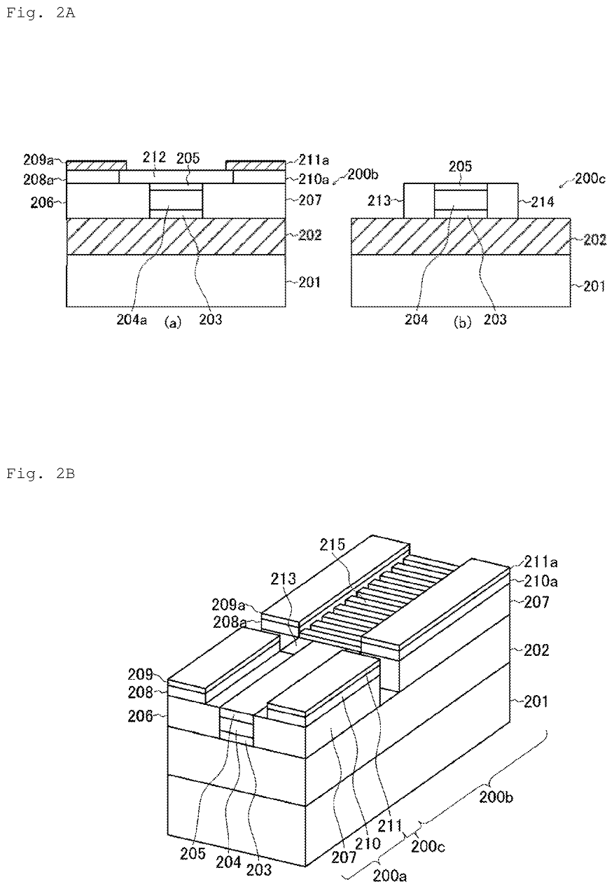

Next, a case where an optical modulation region 200a and a laser region 200b are integrated in the semiconductor optical element according to the embodiment will be described with reference to FIG. 2A and FIG. 2B. As shown in FIG. 2B, the optical modulation region 200a includes a core portion 204 having a multiple quantum-well structure. As shown in FIG. 2A(a), the laser region 200b includes an active portion 204a having a multiple quantum-well structure. In this semiconductor optical element, the optical modulation region 200a and the laser region 200b are optically connected (coupled) to each other via the core portion 204 having a multiple quantum-well structure and the active portion 204a having a multiple quantum-well structure.

In this integration structure, first, a first cladding layer 203 made of n-type (first conduction type) InP doped with Si at a doping concentration of 1×10¹⁸ cm⁻³ is formed on a substrate 201 made of silicon via an insulating layer 202 made of silicon oxide (SiO).

The core portion 204 having a multiple quantum-well structure is formed on the first cladding layer 203. The core portion 204 includes six quantum-well layers made of InGaAsP, for example. The core width of the core portion 204 is about 0.8 μm.

A second cladding layer 205 made of p-type (second conduction type) InP doped with Zn at a doping concentration of 1×10¹⁸ cm⁻³ is formed on the core portion 204. It should be noted that the total thickness of the first cladding layer 203, the core portion 204, and the second cladding layer 205 is about 350 nm.

On the insulating layer 202, a third cladding layer 206 made of n-type (first conduction type) InP doped with Si at a doping concentration of 1×10¹⁸ cm⁻³ is formed on one side portion of the core portion 204. A fourth cladding layer 207 made of p-type (second conduction type) InP doped with Zn at a doping concentration of 1×10¹⁸ cm⁻³ is formed on the other side portion of the core portion 204. The third cladding layer 206 and the fourth cladding layer 207 each have a thickness of about 350 nm. For example, the top face of the third cladding layer 206, the top face of the second cladding layer 205, and the top face of the fourth cladding layer 207 are flush with one another and are flattened.

In the optical modulation region 200a, an n electrode (first electrode) 209 is formed on the third cladding layer 206 via a contact layer 208 made of n-type InGaAs. A p electrode (second electrode) 211 is formed on the fourth cladding layer 207 via a contact layer 210 made of p-type InGaAs.

In the laser region 200b, an n electrode 209a is formed on the third cladding layer 206 via a contact layer 208a made of n-type InGaAs. A p electrode 211a is formed on the fourth cladding layer 207 via a contact layer 210a made of p-type InGaAs. Moreover, in the laser region 200b, an insulating protective layer 212 that is made of silicon nitride and has a thickness of 20 nm, for example, is formed on the active portion 204a having a multiple quantum-well structure. A λ/4-shifted diffraction grating structure 215 that is made of silicon nitride and silicon oxide and has a Bragg wavelength of 1.55 μm is formed on the active portion 2o4a in the laser region 200b by processing a portion of the insulating protective layer 212.

In a connection region 200c located between the optical modulation region 200a and the laser region 200b, semiconductor layers 213 and 214 made of non-doped i-type InP are formed on two side portions of the core portion 204.

It should be noted that the first cladding layer 203 and the second cladding layer 205 are shared by the optical modulation region 200a, the laser region 200b, and the connection region 200c. The third cladding layer 206 and the fourth cladding layer 207 in the optical modulation region 200a respectively have the same configurations as those of the third cladding layer 206 and fourth cladding layer 207 in the laser region 200b.

For example, the length of the active layer of the core portion 204 in the optical modulation region 200a is 200 μm, and the length of the active layer of the active portion 204a in the laser region 200b is 600 μm. The length of the connection region 200c in the light guiding direction is 20 μm. The wavelength between ground levels of the quantum-well layers of the core portion 204 in the optical modulation region 200a is 1.48 μm, and the exciton peak wavelength is 1.49 μm. The light emission wavelength of the quantum-well layers of the active portion 204a in the laser region 200b is 1.55 μm.

The optical modulation region 200a and the laser region 200b can be separated by removing the third cladding layer 206 and the fourth cladding layer 207 in the connection region 200c located between the optical modulation region 200a and the laser region 200b by etching. The third cladding layer 206 and the fourth cladding layer 207 in the optical modulation region 200a and the laser region 200b are formed in necessary portions of the optical modulation region 200a and the laser region 200b.

When the semiconductor optical element having this waveguide structure is produced, a well-known technique such as wafer bonding can be used to form the layers made of a compound semiconductor such as InP on the insulating layer 202. A common crystal growth method such as a known metal organic vapor phase epitaxial method (MOVPE) can be used for crystal growth of InP, InGaAsP, and the like. A common method of producing a semiconductor laser such as a known lithography technique, wet etching, or dry etching can be used to produce a laser waveguide structure and a diffraction grating.

It is sufficient that the third cladding layer 206 and the fourth cladding layer 207 arranged on the two sides in the horizontal direction of the core portion 204 (active portion 204a) is respectively formed through embedded regrowth of n-type doped InP and p-type doped InP in a thin InP layer (not shown) that has been formed on the insulating layer 202. A configuration may also be employed in which non-doped InP is subjected to embedded regrowth and then dopants are introduced thereinto using a technique such as ion implantation or thermal diffusion after the core portion 204 (active portion 204a) has been formed. The diffraction grating 215 can be formed through pattern formation using electron beam exposure and etching, etc.

In the optical modulation region 200a, the n electrode 209 and the p electrode 211 are used to apply a reverse bias between the third and first cladding layers 206 and 203 and the fourth and second cladding layers 207 and 205. As a result, electric fields are applied to the core portion 204 in the optical modulation region 200a, and thus modulation is performed. On the other hand, in the laser region 200b, the n electrode 209a and the p electrode 211a are used to apply a forward bias between the third and first cladding layers 206 and 203 and the fourth and second cladding layers 207 and 205. As a result, an electric current flows in the active portion 204a in the laser region 200b, and thus laser oscillation is performed.

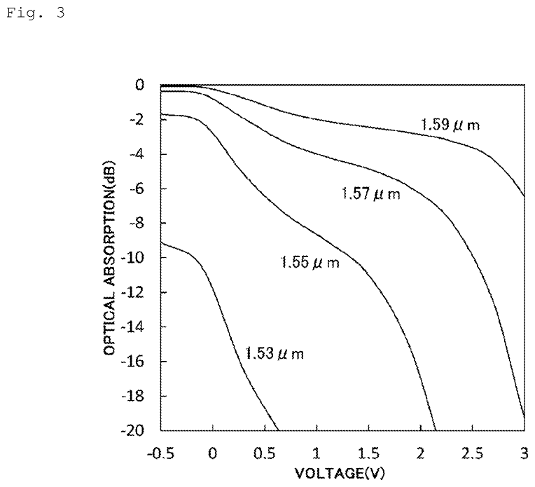

Next, the quenching properties of the above-described optical modulation region 200a will be described with reference to FIG. 3. As shown in FIG. 3, the quenching properties are obtained over a wide voltage region and a wide wavelength region. Accordingly, with embodiments of the present invention, an electro absorption modulator that is driven at a low voltage and exhibits quenching properties over a wide wavelength band can be realized, and this modulator can be easily integrated with a DFB laser. In particular, with the above-described embodiment, the first cladding layer 203, the core portion 204, and the second cladding layer 205 are formed on the insulating layer 202 made of SiO₂, which has a low refractive index, such that the total thickness is 350 nm, and therefore, optical confinement in the core portion 204 is improved, thus making it possible to shorten the optical modulation region 200a.

In the above-described embodiment, in addition to the third cladding layer 206 and the fourth cladding layer 207 arranged on the two sides in the lateral direction of the active portion 204a in the laser region 200b, the first cladding layer 203 and the second cladding layer 205 are arranged with the active portion 204a being located therebetween in the vertical direction, and thus an electric current is injected in the vertical direction as well as the lateral direction (see Non Patent Literature 3). As a result, with the laser region 200b of the semiconductor optical element according to the embodiment, current injection efficiency, which is a problem with a lateral current injection structure, is improved, which contributes to an increase in laser output.

With the connection region 200c formed through processing using etching and the like, the optical modulation region 200a and the laser region 200b are completely separated. As described above, using a technique such as ion implantation or thermal diffusion makes it possible to arrange a dopant layer only in a necessary portion. Accordingly, electric separation is favorably ensured. The capacity of the element is mainly determined by a cross section of a portion including the first cladding layer 203, the core portion 204, and the second cladding layer 205, and thus the capacity of the element per unit length is reduced, thus making it possible to realize high-speed response over 50 Gbit/s.

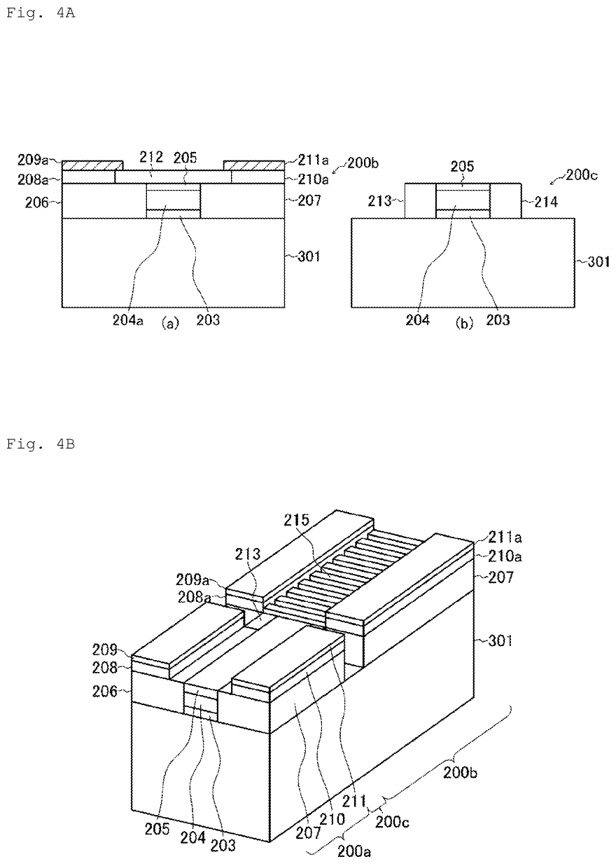

Incidentally, as shown in FIG. 4A and FIG. 4B, an element structure as described above may also be formed on a substrate 301 made of InP that is doped with Fe and is thus made to have semi-insulating properties, for example. The substrate 301 made of semi-insulating InP is used instead of the substrate 201 and insulating layer 202 of the semiconductor optical element described with reference to FIG. 2A and FIG. 2B. The other configurations are the same as described above. In this case, the layers made of a compound semiconductor can be formed on the substrate 301 through epitaxial growth instead of wafer bonding. In this case, it is sufficient that the core portion 204 in the optical modulation region 200a and the connection region 200c, and the active portion 204a in the laser region 200b include twenty quantum-well layers made of InGaAsP, and the total thickness is 400 nm, for example.

Accordingly, using substrate 301 made of InP makes it possible to obtain a high heat dissipation effect. The optical mode extends in the region of the low-loss semi-insulating InP, and therefore, the loss is low, which is advantageous for an increase in optical output of the laser.

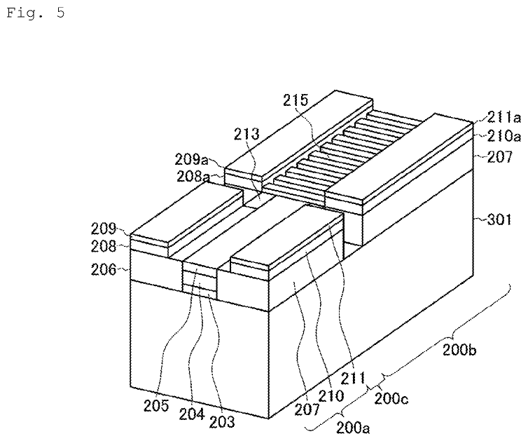

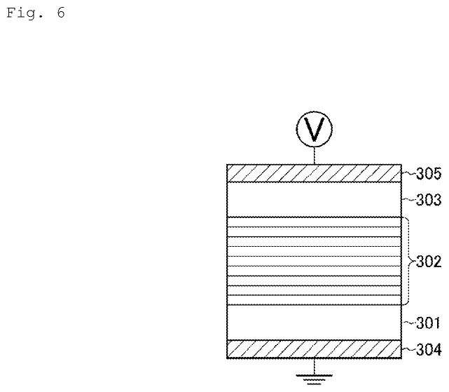

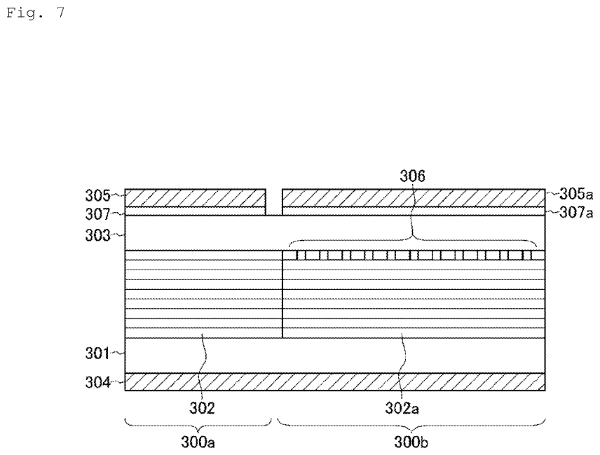

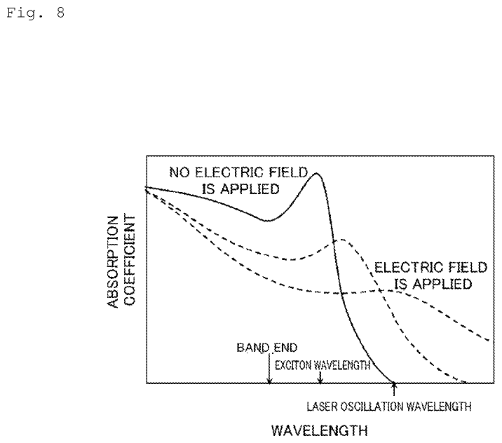

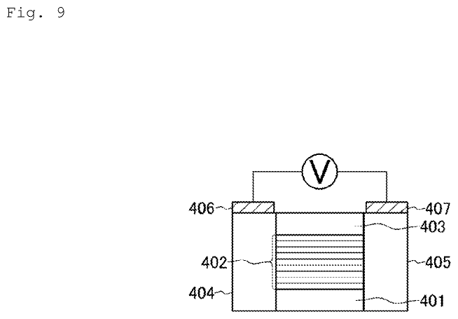

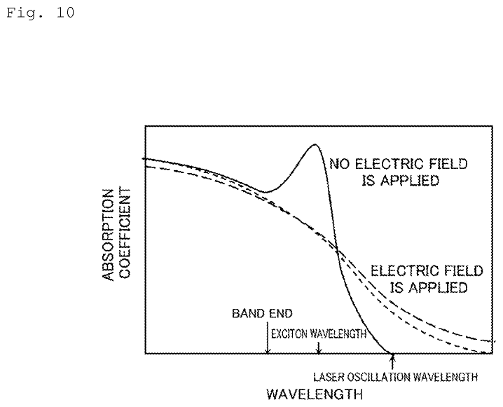

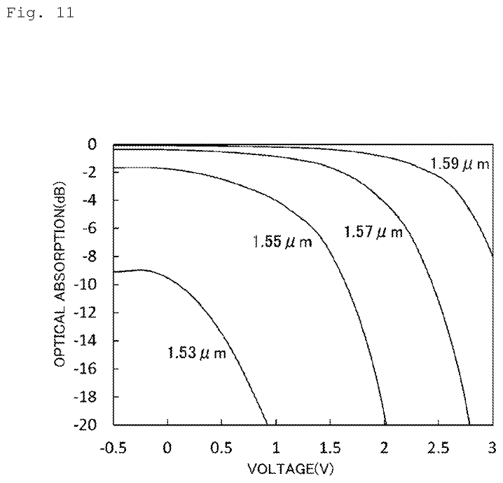

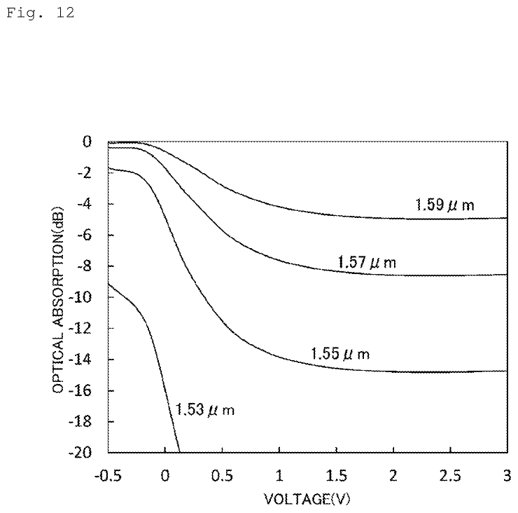

As shown in FIG. 5, a configuration may also be employed in which a first optical confinement separate layer 108 is provided between the first cladding layer 101 and the core portion 102, and a second optical confinement separate layer 1o is provided between the core portion 102 and the second cladding layer 103. It is sufficient that the first optical confinement separate layer 108 and the second optical confinement separate layer 1o are made of an i-type compound semiconductor. Accordingly, a transmission-loss suppressing effect can be obtained by arranging the core portion 102 away from layers to which a p-type dopant is introduced.

As described above, with embodiments of the present invention, the configuration is employed in which the first conduction type first cladding layer and the second conduction type second cladding layer are arranged on the two sides in the vertical direction of the core portion having a multiple quantum-well structure, and the first conduction type third cladding layer and the second conduction type fourth cladding layer are arranged on the two sides in the horizontal direction of the core portion, and a reverse bias is applied thereto, and thus a sufficient quenching ratio is obtained in a wide wavelength region at a low voltage when performing electro-absorption optical modulation.

It should be noted that the present invention is not limited to the embodiment described above, and it is obvious that many modifications and combinations can be made by those ordinarily skilled in the art within the scope of the technical idea of the present invention.

For example, the case where the operating wavelength is set to 1.55 μm was described in the description above, but there is no limitation to this case, and the other operating wavelength such as a 1.3-μm band can be realized within the scope of a design change. A configuration in which an InGaAsP-based laser is formed on an InP substrate and the operating wavelength is within a range from 1 μm to 2 μm can be realized, for example. Although the core portion was made of an InGaAsP-based material, other compound semiconductor materials such as an InGaAlAs-based material can also be used. Although the diffraction grating was made of SiN and SiO₂, a diffraction grating made of another insulating material such as SiON or SiOₓ may also be used. The diffraction grating may also be formed by etching the surface of the second cladding layer. Moreover, the diffraction grating may be arranged on the lower side of the core portion, or arranged on both the upper side and the lower side of the core portion. Furthermore, the case where the first conduction type is the n-type and the second conduction type is the p-type was described in the description above, but it is needless to say that a configuration may also be employed in which the first conduction type is the p-type and the second conduction type is the n-type.

### REFERENCE SIGNS LIST

101 First cladding layer

102 Core portion

103 Second cladding layer

104 Third cladding layer

105 Fourth cladding layer

106 First electrode

107 Second electrode.

1.-4. (canceled)

5. A semiconductor optical element comprising:
a first cladding layer made of a first compound semiconductor, the first compound semiconductor being of a first conduction type;
a core portion on the first cladding layer and serves as an active region having a multiple quantum-well structure, the multiple quantum-well structure including a barrier layer made of a second compound semiconductor and a quantum-well layer made of a third compound semiconductor;
a second cladding layer on the core portion and is made of a fourth compound semiconductor, the fourth compound semiconductor being of a second conduction type;
a third cladding layer on the core portion, the third cladding layer is made of a fifth compound semiconductor, the fifth compound semiconductor being of the first conduction type; and
a fourth cladding layer on an opposing side of the core portion as the third cladding layer, the fourth cladding layer is made of a sixth compound semiconductor, the sixth compound semiconductor being of the second conduction type, wherein a reverse bias is applied between the first cladding layer and the third cladding layer and between the second cladding layer and the fourth cladding layer, and wherein the first cladding layer, the second cladding layer, the third cladding layer, and the fourth cladding layer applies an electric field to the core portion.

6. The semiconductor optical element according to claim 5, further comprising:
a first optical confinement separate layer between the first cladding layer and the core portion, wherein the first optical confinement separate layer is made of a first i-type compound semiconductor; and
a second optical confinement separate layer between the core portion and the second cladding layer, wherein the second optical confinement separate layer is made of a second i-type compound semiconductor.

7. The semiconductor optical element according to claim 5, further comprising:
a first electrode connected to the third cladding layer; and
a second electrode connected to the fourth cladding layer.

8. The semiconductor optical element according to claim 5, wherein an optical modulation region includes the first cladding layer, the second cladding layer, the core portion, the third cladding layer, and the fourth cladding layer, and wherein the semiconductor optical element further comprises:
a laser region including an active portion having a multiple quantum-well structure that shares the first cladding layer and the second cladding layer with the optical modulation region, and
a diffraction grating on the active portion, wherein the optical modulation region and the laser region are insulated and separated from each other, and wherein the optical modulation region and the laser region are optically connected to each other.

9. The semiconductor optical element according to claim 5, wherein the first conduction type is n-type, and wherein the second conduction type is p-type.

10. The semiconductor optical element according to claim 5, wherein the first cladding layer is between the third cladding layer and the fourth cladding layer.

11. The semiconductor optical element according to claim 5, wherein the second cladding layer is between the third cladding layer and the fourth cladding layer.

12. A method comprising:
providing a first cladding layer made of a first compound semiconductor, the first compound semiconductor being of a first conduction type;
forming a core portion on the first cladding layer, wherein the core portion serves as an active region having a multiple quantum-well structure;
forming a second cladding layer on the core portion, the second cladding layer being made of a fourth compound semiconductor, and the fourth compound semiconductor being of a second conduction type;
forming a third cladding layer on the core portion, the third cladding layer being made of a fifth compound semiconductor, and the fifth compound semiconductor being of the first conduction type; and
forming a fourth cladding layer on an opposing side of the core portion as the third cladding layer, the fourth cladding layer being made of a sixth compound semiconductor, and the sixth compound semiconductor being of the second conduction type; and
applying a reverse bias is applied between the first cladding layer and the third cladding layer and between the second cladding layer and the fourth cladding layer, wherein the first cladding layer, the second cladding layer, the third cladding layer, and the fourth cladding layer applies an electric field to the core portion.

13. The method according to claim 12, wherein the multiple quantum-well structure includes a barrier layer made of a second compound semiconductor and a quantum-well layer made of a third compound semiconductor.

14. The method according to claim 12, further comprising:
forming a first optical confinement separate layer between the first cladding layer and the core portion, wherein the first optical confinement separate layer is made of a first i-type compound semiconductor; and
forming a second optical confinement separate layer between the core portion and the second cladding layer, wherein the second optical confinement separate layer is made of a second i-type compound semiconductor.

15. The method according to claim 12, further comprising:
connecting a first electrode to the third cladding layer; and
connecting a second electrode to the fourth cladding layer.

16. The method according to claim 12, wherein an optical modulation region includes the first cladding layer, the second cladding layer, the core portion, the third cladding layer, and the fourth cladding layer, and wherein the method further comprises:
forming a diffraction grating on an active portion of a laser region, wherein the optical modulation region and the laser region are insulated and separated from each other, wherein the optical modulation region and the laser region are optically connected to each other, and wherein the active portion has a multiple quantum-well structure that shares the first cladding layer and the second cladding layer with the optical modulation region.

17. The method according to claim 12, wherein the first conduction type is n-type, and wherein the second conduction type is p-type.

18. The method according to claim 12, wherein the first cladding layer is between the third cladding layer and the fourth cladding layer.

19. The method according to claim 12, wherein the second cladding layer is between the third cladding layer and the fourth cladding layer.
